(19) United States
(12) Patent Application Publication
(10) Pub. No.: US 2024/0087927 A1
(43) Pub. Date: Mar. 14, 2024

(54) SUBSTRATE PROCESSING APPARATUS, METHOD OF MANUFACTURING SEMICONDUCTOR DEVICE AND NON-TRANSITORY COMPUTER-READABLE RECORDING MEDIUM

(71) Applicant: Kokusai Electric Corporation, Tokyo (JP)

(72) Inventors: Koichiro HARADA, Toyama (JP); Katsunori FUNAKI, Toyama (JP); Yuichiro TAKESHIMA, Toyama (JP); Van Chieu NGUYEN, Toyama (JP)

(21) Appl. No.: 18/447,533

(22) Filed: Aug. 10, 2023

(30) Foreign Application Priority Data
Sep. 14, 2022 (JP) 2022-146413

(51) Int. Cl. H01L 21/67; H01J 37/32; H01L 21/02

(52) U.S. Cl. CPC H01L 21/67276; H01J 37/321; H01J 37/32449; H01L 21/02274; H01L 21/67017

(57) ABSTRACT

According to the present disclosure, there is provided a technique capable of suppressing a replacement of a quartz vessel due to an occurrence of a crack of the quartz vessel. There is provided a technique including: a quartz vessel provided with a process chamber; a gas supplier; a coil surrounding the quartz vessel and configured to excite a process gas by a plasma generated by supplying a high frequency power to the coil, wherein a distance between the coil and an outer peripheral surface of a first portion of the quartz vessel is set to be greater than a distance between the coil and an outer peripheral surface of a second portion of the quartz vessel, and wherein a silicon hydroxide film is formed on an inner peripheral surface of the first portion and the silicon hydroxide film is not formed on an inner peripheral surface of the second portion.

### CROSS REFERENCE TO RELATED APPLICATIONS

This application claims foreign priority under 35 U.S.C. § 119(a)-(d) to Application No. JP 2022-146413 filed on Sep. 14, 2022, the entire contents of which are hereby incorporated by reference.

### TECHNICAL FIELD

The present disclosure relates to a substrate processing apparatus, a method of manufacturing a semiconductor device and a non-transitory computer-readable recording medium.

### BACKGROUND

Recently, a semiconductor device such as a flash memory tends to be integrated at a high density. As a result, a size of a pattern of the semiconductor device is remarkably miniaturized. A predetermined processing (which serves as a part of a manufacturing process of the semiconductor device) such as an oxidation process and a nitridation process on a substrate may be performed to form the pattern.

For example, according to some related arts, a surface of the pattern formed on the substrate may be modified by performing a modification process by using a plasma-excited process gas.

In a conventional configuration, when processing the substrate, a silicon hydroxide film may be formed on an inner peripheral surface of a quartz vessel. In such a case, when a maintenance is performed for the quartz vessel, a temperature of the quartz vessel may be lowered. When a thickness of the silicon hydroxide film formed on the inner peripheral surface of the quartz vessel increases, a stress acts on the silicon hydroxide film as the temperature of the quartz vessel is lowered. Thereby, a fine crack (microcrack) occurs on the silicon hydroxide film. When the fine crack in the silicon hydroxide film develops and a crack occurs in the quartz vessel as a result, it is preferable to perform a replacement of the quartz vessel.

### SUMMARY

According to the present disclosure, there is provided a technique capable of saving a replacement of a quartz vessel due to an occurrence of a crack of the quartz vessel, which is caused by a silicon hydroxide film formed on an inner peripheral surface of the quartz vessel.

According to one embodiment of the present disclosure, there is provided a technique that includes: a quartz vessel provided with a process chamber in which a substrate is arranged; a gas supplier configured to supply a process gas to the process chamber; and a coil surrounding the quartz vessel and configured to excite the process gas by a plasma generated by supplying a high frequency power to the coil, wherein a distance between the coil and an outer peripheral surface of a first portion of the quartz vessel is set to be greater than a distance between the coil and an outer peripheral surface of a second portion of the quartz vessel, and wherein a silicon hydroxide film is formed on an inner peripheral surface of the first portion and the silicon hydroxide film is not formed on an inner peripheral surface of the second portion.

### BRIEF DESCRIPTION OF THE DRAWINGS

FIG. 1 is a diagram schematically illustrating a vertical cross-section of a substrate processing apparatus according to one or more embodiments of the present disclosure.

FIG. 2 is a diagram schematically illustrating an enlarged view of the substrate processing apparatus according to the embodiments of the present disclosure.

FIG. 3 is a diagram schematically illustrating a perspective view of components such as a shield plate and a resonance coil of the substrate processing apparatus according to the embodiments of the present disclosure.

FIG. 4 is a diagram schematically illustrating a perspective view of the resonance coil of the substrate processing apparatus according to the embodiments of the present disclosure.

FIG. 5 is a diagram schematically illustrating relationships among a winding diameter of the resonance coil, a voltage, a current and an electric field strength of the substrate processing apparatus according to the embodiments of the present disclosure.

FIG. 6 is a diagram schematically illustrating a plan view of components such as the shield plate and a moving structure of the substrate processing apparatus according to the embodiments of the present disclosure.

FIG. 7 is a diagram schematically illustrating a perspective view of the moving structure of the substrate processing apparatus according to the embodiments of the present disclosure.

FIG. 8 is a diagram schematically illustrating another perspective view of the moving structure of the substrate processing apparatus according to the embodiments of the present disclosure.

FIG. 9 is a block diagram schematically illustrating a configuration of a controller and related components of the substrate processing apparatus according to the embodiments of the present disclosure.

FIG. 10 is a flow chart schematically illustrating steps of a method of manufacturing a semiconductor device according to the embodiments of the present disclosure.

FIG. 11 is a diagram schematically illustrating a vertical cross-section of a substrate processing apparatus according to a comparative example of the embodiments of the present disclosure.

FIG. 12 is a diagram schematically illustrating an enlarged view of the substrate processing apparatus according to the comparative example of the embodiments of the present disclosure.

### DETAILED DESCRIPTION

### <Embodiment of Present Disclosure>

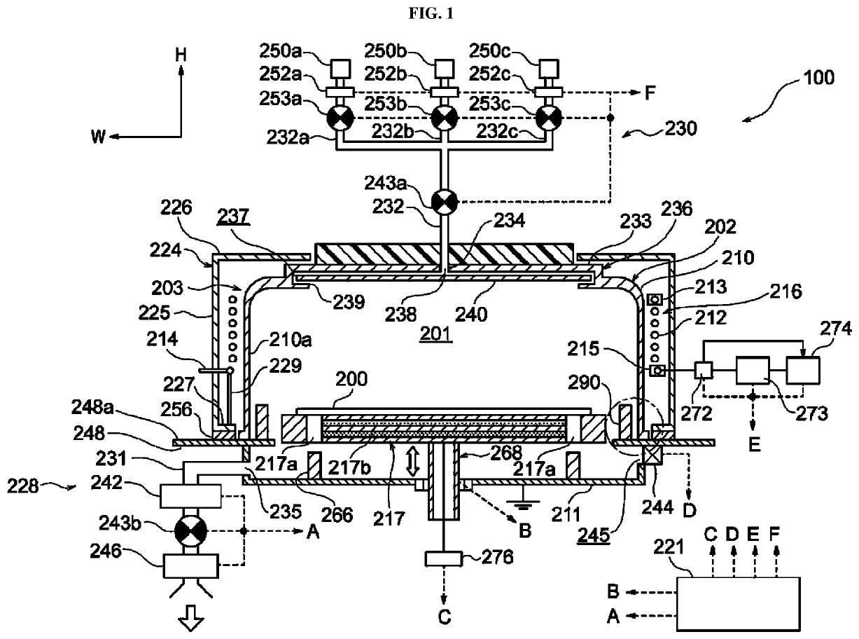

Hereinafter, one or more embodiments (also simply referred to as “embodiments”) of the technique of the present disclosure will be described with reference to FIGS. 1 through 12. The drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match. In the drawings, a direction indicated by an arrow H represents an up-and-down direction (that is, a vertical direction) of a substrate processing apparatus 100, a direction indicated by an arrow W represents a width direction (that is, a horizontal direction) of the substrate processing apparatus 100, and a direction indicated by an arrow D represents a depth direction (that is, another horizontal direction) of the substrate processing apparatus 100. Hereinafter, the up-and-down direction of the substrate processing apparatus 100 may also be simply referred to as an “apparatus up-and-down direction”, the width direction of the substrate processing apparatus 100 may also be simply referred to as an “apparatus width direction”, the depth direction of the substrate processing apparatus 100 may also be simply referred to as an “apparatus depth direction”.

### <Substrate Processing Apparatus 100>

The substrate processing apparatus 100 according to the present embodiments is mainly configured to perform an oxidation process on a film formed on a substrate.

As shown in FIG. 1, the substrate processing apparatus 100 includes a process furnace 202 in which a wafer 200 is processed by using a plasma. The process furnace 202 is provided with a process vessel 203 constituting a process chamber 201. The process vessel 203 may include an upper vessel 210 of a dome shape and a lower vessel 211 of a bowl shape. Further, the substrate processing apparatus 100 includes a base plate 248 that covers an upper end of the lower vessel 211 and that is provided with a through-hole therein. The wafer 200 serves as an example of the substrate described above.

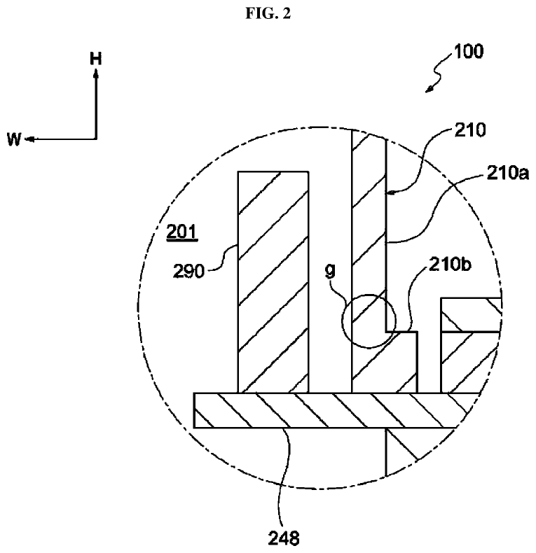

The upper vessel 210 includes a cylinder (cylindrical portion) 210a of a vertically extending cylindrical shape. By covering the lower vessel 211 with the upper vessel 210, the process chamber 201 is defined. For example, the upper vessel 210 may be made of quartz (SiO₂), and the lower vessel 211 may be made of aluminum (Al). Further, as shown in FIG. 2, a flange 210b protruding outward in a radial direction of the upper vessel 210 is provided at a lower end portion of the upper vessel 210 along an entirety of a circumference of the upper vessel 210. Further, the flange 210b is fixed to the base plate 248 by a fixing structure (not shown).

For example, a silicon nitride (also simply referred to as a “SiN film”) serving as a protection film for protecting the upper vessel 210 is formed on an inner peripheral surface of the upper vessel 210. The upper vessel 210 serves as an example of a quartz vessel.

As shown in FIGS. 1 and 2, for example, the process chamber 201 is provided with a cylindrical structure 290 of a cylindrical shape. The cylindrical structure 290 is provided at the lower end portion of the upper vessel 210 along the inner peripheral surface of the upper vessel 210. For example, the cylindrical structure 290 is made of SiO₂, and is attached (or fixed) to the base plate 248. The lower end portion of the upper vessel 210 serves as an example of a portion of the upper vessel 210, the cylindrical structure 290 serves is an example of a partial structure.

As shown in FIG. 1, for example, a gate valve 244 is provided on a lower side wall of the lower vessel 211. While the gate valve 244 is open, the wafer 200 can be transferred (loaded) into the process chamber 201 through a loading/unloading port 245 using a wafer transfer structure (wafer transfer device) (not shown) or can be transferred (unloaded) out of the process chamber 201 through the loading/unloading port 245 using the wafer transfer structure. While the gate valve 244 is closed, the gate valve 244 maintains the process chamber 201 airtight.

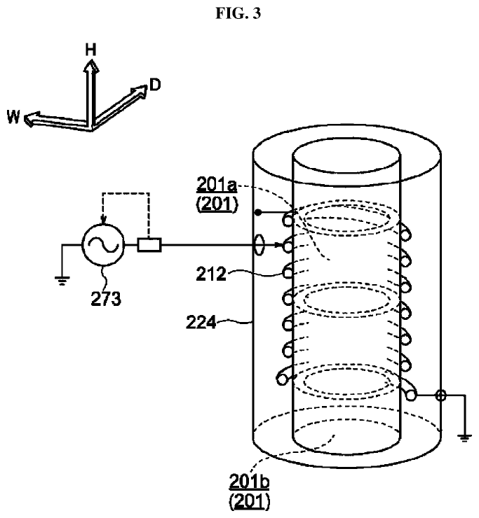

As shown in FIG. 3, for example, the process chamber 201 includes a plasma generation space 201a and a substrate processing space 201b. A resonance coil 212 is provided around the plasma generation space 201a. The substrate processing space 201b communicates with the plasma generation space 201a, and the wafer 200 is processed in the substrate processing space 201b. The plasma generation space 201a refers to a space in which the plasma is generated, for example, a space above a lower end of the resonance coil 212 and below an upper end of the resonance coil 212 in the process chamber 201. In addition, the substrate processing space 201b refers to a space in which the substrate (that is, the wafer 200) is processed by the plasma, for example, a space below the lower end of the resonance coil 212. According to the present embodiments, a horizontal diameter of the plasma generation space 201a in the horizontal direction is set to be substantially the same as a horizontal diameter of the substrate processing space 201b in the horizontal direction.

### <Susceptor 217>

As shown in FIG. 1, for example, a susceptor 217 serving as a part of a substrate mounting table on which the wafer 200 is placed is provided at a center of a bottom portion of the process chamber 201.

A heater 217b serving as a heating structure is integrally embedded in the susceptor 217. The heater 217b is configured to heat the wafer 200 such that a surface of the wafer 200 is heated to a temperature within a range from 25° C. to 750° C. when an electric power is supplied to the heater 217b.

Further, a susceptor elevator 268 including a driver (which is a driving structure) capable of elevating and lowering the susceptor 217 is provided at the susceptor 217. In addition, a plurality of through-holes 217a are provided at the susceptor 217, and a plurality of wafer lift pins 266 are provided at a bottom surface of the lower vessel 211 at locations corresponding to the through-holes 217a. When the susceptor 217 is lowered by the susceptor elevator 268, the wafer lift pins 266 pass through the through-holes 217a without contacting the susceptor 217.

The substrate mounting table according to the present embodiments is constituted mainly by the susceptor 217 and the heater 217b.

### <Gas Supplier 230>

As shown in FIG. 1, a gas supplier (which is a gas supply structure or a gas supply system) 230 is provided above the process chamber 201. Specifically, a gas supply head 236 is provided above the process chamber 201, that is, on an upper portion of the upper vessel 210. The gas supply head 236 includes a lid 233 of a cap shape, a gas inlet port 234, a buffer chamber 237, an opening 238, a shield plate 240 and a gas outlet port 239. In addition, the gas supply head 236 is configured such that a gas such as a reactive gas can be supplied into the process chamber 201 through the gas supply head 236.

A downstream end of an oxygen-containing gas supply pipe 232a through which oxygen gas (O2 gas) serving as an oxygen-containing gas is supplied, a downstream end of a hydrogen-containing gas supply pipe 232b through which hydrogen gas (H2 gas) serving as a hydrogen-containing gas is supplied and a downstream end of an inert gas supply pipe 232c through which an inert gas such as argon (Ar) gas is supplied are connected to a gas supply pipe 232 of the gas inlet port 234 so as to be conjoined with one another.

A mass flow controller (MFC) 252a serving as a flow rate controller and a valve 253a serving as an opening/closing valve are sequentially provided at the oxygen-containing gas supply pipe 232a in this order from an upstream side to a downstream side of the oxygen-containing gas supply pipe 232a in a gas flow direction. An MFC 252b and a valve 253b are sequentially provided at the hydrogen-containing gas supply pipe 232b in this order from an upstream side to a downstream side of the hydrogen-containing gas supply pipe 232b in the gas flow direction. An MFC 252c and a valve 253c are sequentially provided at the inert gas supply pipe 232c in this order from an upstream side to a downstream side of the inert gas supply pipe 232c in the gas flow direction. Although not included in the substrate processing apparatus 100, an O2 gas supply source 250a is provided at an upstream side of the MFC 252a of the oxygen-containing gas supply pipe 232a, a H2 gas supply source 250b is provided at an upstream side of the MFC 252b of the hydrogen-containing gas supply pipe 232b, and an Ar gas supply source 250c is provided at an upstream side of the MFC 252c of the inert gas supply pipe 232c.

A valve 243a is provided at the gas supply pipe 232 at a downstream side of a location where the oxygen-containing gas supply pipe 232a, the hydrogen-containing gas supply pipe 232b and the inert gas supply pipe 232c join. The valve 243a is connected to an upstream side of the gas inlet port 234.

The gas supplier (gas supply system) 230 according to the present embodiments is constituted mainly by the gas supply head 236 (which is constituted by the lid 233, the gas inlet port 234, the buffer chamber 237, the opening 238, the shield plate 240 and the gas outlet port 239), the oxygen-containing gas supply pipe 232a, the hydrogen-containing gas supply pipe 232b, the inert gas supply pipe 232c, the MFCs 252a, 252b and 252c, the valves 253a, 253b, 253c and 243a. However, the gas supplier 230 may further include the O2 gas supply source 250a, the H2 gas supply source 250b and the Ar gas supply source 250c.

### <Exhauster 228>

As shown in FIG. 1, for example, an exhauster (which is an exhaust structure or an exhaust system) 228 is provided below the process chamber 201 so as to face the loading/unloading port 245 in the horizontal direction. Specifically, a gas exhaust port 235 through which the reactive gas is exhausted from the process chamber 201 is provided on the lower side wall of the lower vessel 211. An upstream end of a gas exhaust pipe 231 is connected to the gas exhaust port 235. An APC (Automatic Pressure Controller) valve 242 serving as a pressure regulator (which is a pressure adjusting structure), a valve 243b serving as an opening/closing valve and a vacuum pump 246 serving as a vacuum exhaust apparatus are sequentially provided at the gas exhaust pipe 231 in this order from an upstream side to a downstream side of the gas exhaust pipe 231 in the gas flow direction.

The exhauster 228 according to the present embodiments is constituted mainly by the gas exhaust port 235, the gas exhaust pipe 231, the APC valve 242 and the valve 243b. However, the exhauster 228 may further include the vacuum pump 246.

### <Plasma Generator 216>

As shown in FIG. 1, for example, a plasma generator (which is a plasma generating structure) 216 is provided mainly at an outer side of an outer wall of the cylinder 210a of the upper vessel 210. Specifically, a resonance coil 212 of a spiral shape is provided around an outer periphery of the process chamber 201, that is, around an outer side of a side wall of the upper vessel 210 so as to surround the process chamber 201. In other words, the resonance coil 212 of the spiral shape is provided so as to surround the process vessel 203 from the outer side (which is a side away from a center of the cylinder 210a) of the cylinder 210a in a radial direction of the cylinder 210a (hereinafter, also referred to as a “vessel radial direction”). The resonance coil 212 acts as an electrode, and serves as an example of a coil.

For example, an RF (Radio Frequency) sensor 272, a high frequency power supply 273 and a matcher (which is a matching structure) 274 are connected to the resonance coil 212. The matcher 274 is configured to perform an impedance matching or an output frequency matching for the high frequency power supply 273.

### —High Frequency Power Supply 273, RF Sensor 272 and Matcher 274—

The high frequency power supply 273 is configured to supply a high frequency power (RF power) to the resonance coil 212. The RF sensor 272 is provided at an output side of the high frequency power supply 273. The RF sensor 272 is configured to monitor information of a traveling wave or reflected wave of the high frequency power supplied from the high frequency power supply 273. The power of the reflected wave monitored by the RF sensor 272 is input to the matcher 274, and the matcher 274 is configured to control (or adjust) an impedance of the high frequency power supply 273 or a frequency of the high frequency power output from the high frequency power supply 273 so as to minimize the reflected wave based on the information of the reflected wave input from the RF sensor 272.

The high frequency power supply 273 includes a power supply controller (which is a control circuit) (not shown) and an amplifier (which is an output circuit) (not shown). The power supply controller includes a high frequency oscillation circuit (not shown) and a preamplifier (not shown) in order to adjust an oscillation frequency and an output. The amplifier amplifies the output to a predetermined output level. The power supply controller controls the amplifier based on output conditions relating to the frequency and the power, which are set in advance through an operation panel (not shown). The amplifier supplies a constant high frequency power to the resonance coil 212 via a transmission line (not shown).

### —Resonance Coil 212—

A winding diameter, a winding pitch and the number of winding turns of the resonance coil 212 are set such that the resonance coil 212 resonates at a constant wavelength to form a standing wave of a predetermined wavelength. That is, an electrical length of the resonance coil 212 is set to an integral multiple (1 time, 2 times, or so on) of a wavelength of a predetermined frequency of the high frequency power supplied from the high frequency power supply 273. In other words, the substrate processing apparatus 100 includes the high frequency power supply 273 capable of supplying the high frequency power to the electrode in a state where the electrical length of the resonance coil 212 is set to the integral multiple of the wavelength of the predetermined frequency of the high frequency power supplied from the high frequency power supply 273.

Specifically, considering conditions such as the power to be applied, a strength of a magnetic field to be generated and a shape of an apparatus such as the substrate processing apparatus 100 to which the power is to be applied to, the resonance coil 212 whose effective cross-section is within a range from 50 mm2 to 300 mm2 and whose diameter is within a range from 200 mm to 500 mm is wound, for example, twice to 60 times around an outer circumference of a room constituting the plasma generation space 201a (see FIG. 3) such that the magnetic field of about 0.01 Gauss to about 10 Gauss can be generated by the high frequency power whose frequency is within a range from 800 kHz to 50 MHz and whose power is within a range from 0.5 KW to 5 KW.

In the present specification, a notation of a numerical range such as “from 800 kHz to 50 MHz” means that a lower limit and an upper limit are included in the numerical range. Therefore, for example, a numerical range “from 800 kHz to 50 MHz” means a range equal to or higher than 800 kHz and equal to or less than 50 MHz. The same also applies to other numerical ranges described herein.

According to the preferred embodiments, for example, the frequency of the high frequency power is set to 13.56 MHz or 27.12 MHz. According to the present embodiments, the frequency of the high frequency power is set to 27.12 MHz and the electrical length of the resonance coil 212 is set equal to the wavelength of the high frequency power (about 11 meters). For example, the winding pitch of the resonance coil 212 is set at equal intervals of 24.5 mm. For example, the winding diameter (diameter) of the resonance coil 212 is set to be greater than a diameter of the wafer 200. According to the present embodiments, for example, the diameter of the wafer 200 is set to 300 mm, and the winding diameter of the resonance coil 212 is set to 500 mm, which is greater than the diameter of the wafer 200.

For example, a copper pipe, a copper thin plate, an aluminum pipe, an aluminum thin plate, a material obtained by depositing copper or aluminum on a polymer belt may be used as a material constituting the resonance coil 212.

Further, both ends of the resonance coil 212 are electrically grounded. At least one end of the resonance coil 212 is grounded via a movable tap 213 in order to fine-tune the electrical length of the resonance coil 212 when the substrate processing apparatus 100 is newly installed or process conditions of the substrate processing apparatus 100 are changed. A reference numeral 214 shown in FIG. 1 indicates a fixed ground at the other end of the resonance coil 212. Further, a power feeder (not shown) constituted by a movable tap 215 is provided between the grounded ends of the resonance coil 212 in order to fine-tune the impedance of the resonance coil 212 when the substrate processing apparatus 100 is newly installed or the process conditions of the substrate processing apparatus 100 are changed.

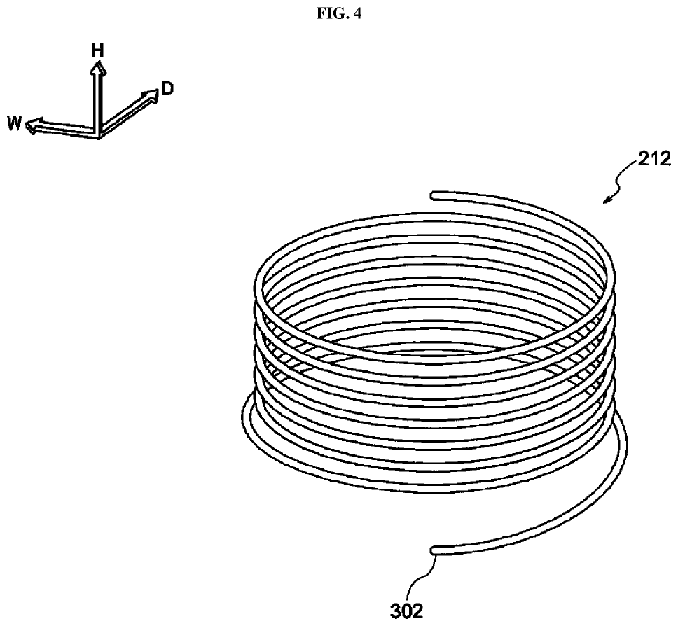

As shown in FIG. 4, for example, the resonance coil 212 is configured such that the winding diameter of the resonance coil 212 expands at a first grounding point 302 where the movable tap 215 (see FIG. 1) on a lower end portion of the resonance coil 212 is provided. As a result, the winding diameter of the resonance coil 212 at the first grounding point 302 is different from the winding diameter of the resonance coil 212 at portions above the first grounding point 302.

That is, in the radial direction of the upper vessel 210, as shown in FIG. 1, regarding a distance between an outer peripheral surface of the upper vessel 210 and a peripheral surface of the resonance coil 212, the distance is set to be greater at the lower end portion of the resonance coil 212 than at the other portions of the resonance coil 212 (see FIG. 4). In other words, the distance between the peripheral surface of the lower end portion of the resonance coil 212 and the outer peripheral surface of the upper vessel 210 is set to be greater than the distance between the peripheral surface of each of the other portions of the resonance coil 212 and the outer peripheral surface of the upper vessel 210. According to the present embodiments, in the radial direction of the upper vessel 210, the distance between the peripheral surface of the lower end portion of the resonance coil 212 and the outer peripheral surface of the upper vessel 210 is set to be equal to or greater than 8 mm. The distance of 8 mm serves as an example of a predetermined value (distance).

### —Shield Plate 224—

As shown in FIG. 1, for example, a shield plate 224 is provided to cover the resonance coil 212 from an outer side in reference to the vessel radial direction. The shield plate 224 is provided to shield its inside from an electric field generated by the resonance coil 212 and to form a capacitive component (also referred to as a “C component”) of the resonance coil 212 for constructing a resonance circuit between the shield plate 224 and the resonance coil 212.

Specifically, for example, the shield plate 224 may include: a primary structure (main structure) 225 (which is of a cylindrical shape) made of a conductive material such as an aluminum alloy and configured to cover the resonance coil 212 from the outer side in reference to the vessel radial direction; and an upper flange 226 connected to an upper end of the primary structure 225 and extending inward in reference to the vessel radial direction. The shield plate 224 may further include a lower flange 227 connected to a lower end of the primary structure 225 and extending inward in reference to the vessel radial direction.

The resonance coil 212 described above is supported by a plurality of supports 229 vertically installed on an upper end surface of the lower flange 227. For example, a support plate 256 is provided to be placed on the base plate 248. The support plate 256 is provided with a through-hole through which the upper vessel 210 passes. The shield plate 224 is supported by the support plate 256 from thereunder. In other words, the support plate 256 supports the shield plate 224 and the resonance coil 212 from thereunder. In addition, for example, the shield plate 224 is disposed about 5 mm to 150 mm apart from an outer circumference of the resonance coil 212.

The plasma generator 216 according to the present embodiments is constituted mainly by the resonance coil 212, the RF sensor 272 and the matcher 274. However, the plasma generator 216 may further include the high frequency power supply 273.

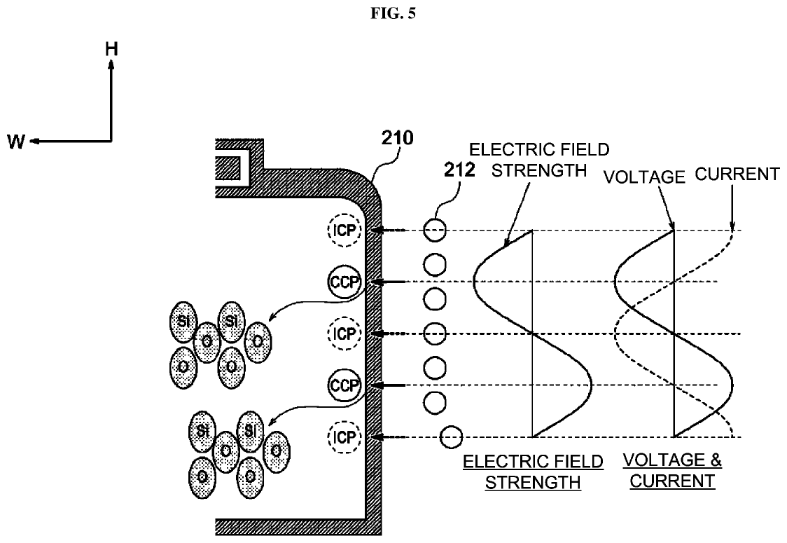

Hereinafter, a principle of generating the plasma in the substrate processing apparatus 100 according to the present embodiments and properties of the generated plasma will be described with reference to FIGS. 3 and 5.

A plasma generation circuit constituted by the resonance coil 212 is configured as an RLC parallel resonance circuit. However, in the plasma generation circuit, an actual resonance frequency of the resonance coil 212 may fluctuate slightly. For example, when the plasma is generated, the actual resonance frequency may fluctuate slightly depending on conditions such as a variation (change) in a capacitive coupling between a voltage portion of the resonance coil 212 and the plasma, a variation in an inductive coupling between the plasma generation space 201a and the plasma and an excitation state of the plasma.

Therefore, according to the present embodiments, for example, the matcher 274 is configured to increase or decrease the impedance or the output frequency of the high frequency power supply 273 such that the electric power of the reflected wave is minimized based on the electric power of the reflected wave from the resonance coil 212 detected by the RF sensor 272 when the plasma is generated. In this manner, the deviation in the resonance occurring at the resonance coil 212 when the plasma generation is compensated by the power supply.

With such a configuration, as shown in FIG. 3, the high frequency power in accordance with the actual resonance frequency of the resonance coil 212 combined with the plasma is supplied to the resonance coil 212 according to the present embodiments (or the high frequency power is supplied to match an actual impedance of the resonance coil 212 combined with the plasma). Therefore, the standing wave in which the phase voltage thereof and the opposite phase voltage thereof are always canceled out by each other is generated in the resonance coil 212. When the electrical length of the resonance coil 212 and the wavelength of the high frequency power are the same, the highest phase current is generated at an electric midpoint of the resonance coil 212 (node with zero voltage). Therefore, a donut-shaped induction plasma whose electric potential is extremely low is generated in the vicinity of the electric midpoint of the resonance coil 212. The donut-shaped induction plasma is hardly capacitively coupled with a wall of the process chamber 201 or the susceptor 217.

Specifically, as shown in FIG. 5, an amplitude of the standing wave of the current is maximized at both ends (that is, the lower end and the upper end) of the resonance coil 212 and the electric midpoint of the resonance coil 212. A high frequency magnetic field is generated in the vicinity of a position where the amplitude of the current is maximized, and the plasma of a process gas (which is the reactive gas supplied to the process chamber 201) is generated by the high frequency magnetic field. Hereinafter, the plasma of the process gas generated in a manner described above may also be referred to as an “ICP (Inductively Coupled Plasma) component plasma”. The ICP component plasma generated in a donut shape in regions (which are indicated by dashed lines) is concentrated in the vicinity of the electric midpoint of the resonance coil 212 and both ends of the resonance coil 212.

On the other hand, an amplitude of the standing wave of the voltage is minimized (ideally zero) at both ends (that is, the lower end and the upper end) of the resonance coil 212 and the electric midpoint of the resonance coil 212, and is maximized at a position therebetween. A high frequency electric field is generated in the vicinity of a position where the amplitude of the voltage is maximized, and the plasma of the process gas is generated by the high frequency electric field. Hereinafter, the plasma of the process gas generated in a manner described above may also be referred to as a “CCP (Capacitively Coupled Plasma) component plasma”. The CCP component plasma generated in a donut shape is concentrated in regions (which are indicated by dotted lines) between the lower end and the electric midpoint of the resonance coil 212 and between the upper end and the electric midpoint of the resonance coil 212 in a space along the inner peripheral surface of the upper vessel 210.

Reactive species such as radicals and ions and electrons (electric charges) are generated from the CCP component plasma. Positive electrons (electric charges) generated in a manner described above are attracted to the inner peripheral surface of the upper vessel 210 by the electric field generating the CCP component plasma, and the inner peripheral surface of the upper vessel 210 is charged with the positive electrons (electric charges). Then, negative ions (in particular, negative ions with a large mass) generated by exciting the CCP component plasma are accelerated toward the inner peripheral surface of the upper vessel 210 charged with the positive electrons (electric charges), and collide with the inner peripheral surface of the upper vessel 210. Therefore, the inner peripheral surface of the upper vessel 210 is subject to sputtering. The inner peripheral surface of the upper vessel 210 is scraped at a portion subject to the sputtering as above.

### <Mover 310>

A mover (which is a moving structure) 310 is configured to move the resonance coil 212 with respect to the process vessel 203.

Due to factors such as a variation in a position of the resonance coil 212 and a variation in a shape of the process vessel 203, the distance between the outer peripheral surface of the upper vessel 210 and the peripheral surface of the resonance coil 212 in the radial direction of the upper vessel 210 may become smaller than a predetermined value (predetermined distance). Although the details will be described later, in a case where the distance between the outer peripheral surface of the upper vessel 210 and the peripheral surface of the resonance coil 212 is small as described above, a silicon hydroxide film (SiOH film) is formed on the upper vessel 210 during the wafer 200 being processed. Due to the SiOH film, a crack may occur in the upper vessel 210.

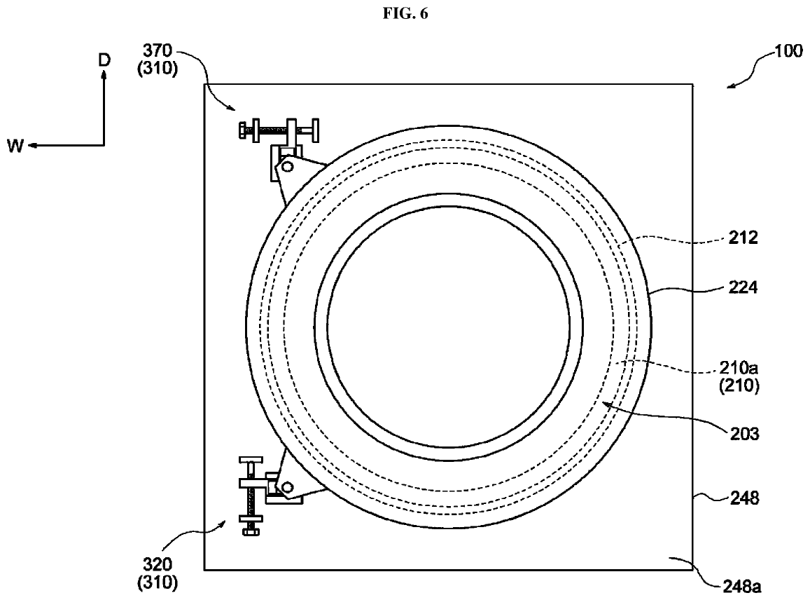

As shown in FIG. 6, the mover 310 configured to move the resonance coil 212 with respect to the process vessel 203 is provided on an upper surface 248a of the base plate 248, and is constituted by a first mover (which is a first moving structure) 320 and a second mover (which is a second moving structure) 370.

The first mover 320 is configured to move the resonance coil 212 and the shield plate 224 in the apparatus depth direction (which is the vessel radial direction), and the second mover 370 is configured to move the resonance coil 212 and the shield plate 224 in the vessel radial direction and in the apparatus width direction perpendicular to the apparatus depth direction.

### —First Mover 320—

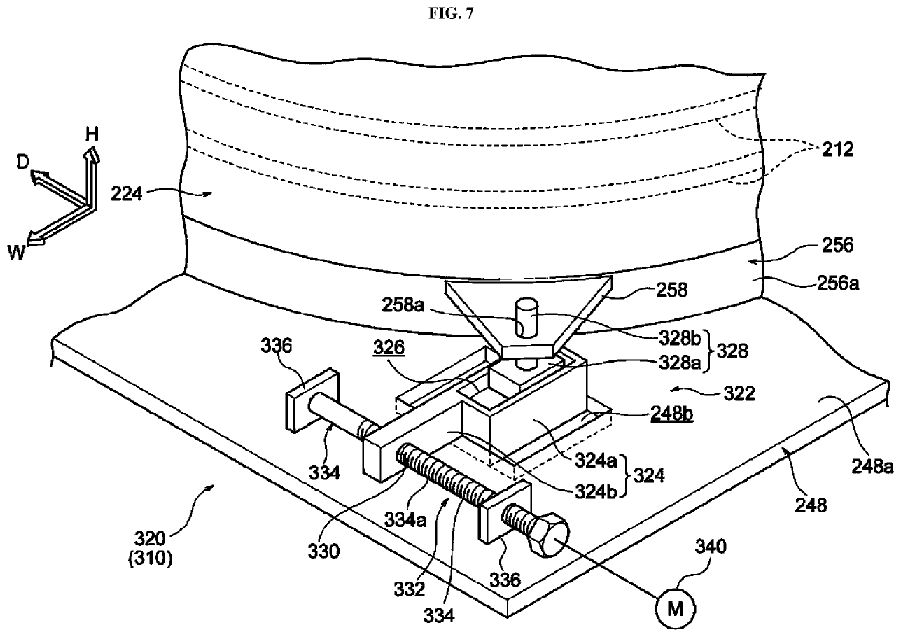

As shown in FIG. 6, for example, the first mover 320 is provided on the base plate 248 to be located close to a front end (lower end in the page) of the base plate 248 in the apparatus depth direction and also close to a lateral end (left end in the page) of the base plate 248 in the apparatus width direction. As shown in FIG. 7, the first mover 320 may include: a movable structure 322 indirectly attached to the resonance coil 212 and configured to move integrally with the resonance coil 212; a regulator (which is an adjusting structure) 332 serving as a structure configured to adjust a position of the movable structure 322 by moving the movable structure 322 when operated; and a driver (which is a driving structure) 340 such as a stepping motor. In the present specification, “to move integrally with” means “to move without changing a relative relationship with”.

### —Movable Structure 322 of First Mover 320—

As shown in FIG. 7, the movable structure 322 may include a primary structure (main structure) 324 and a support structure 328 supported by the primary structure 324.

The primary structure 324 may include: a base 324a of a rectangular parallelepiped shape extending in the apparatus width direction; and an extension structure 324b of a plate shape extending from the base 324a toward the lateral end of the base plate 248 in the apparatus width direction. A lower end portion of the base 324a is inserted into a guide groove 248b provided (formed) on the upper surface 248a of the base plate 248. As a result, the primary structure 324 is guided by the guide groove 248b to move in the apparatus depth direction. Further, a guide groove 326 extending in the apparatus width direction is provided (formed) on an upper surface of the base 324a.

Further, the extension structure 324b is of a rectangular shape extending in the apparatus width direction when viewed from the apparatus depth direction, wherein a plate thickness direction is defined as the apparatus depth direction. A female screw 330 is provided (formed) in the extension structure 324b so as to penetrate the extension structure 324b in the apparatus depth direction.

For example, the support structure 328 may include: a base 328a of a rectangular parallelepiped shape extending in the apparatus width direction; and a column structure 328b of a column shape projecting upward from the base 328a. A portion of the base 328a other than an upper end portion thereof is inserted into the guide groove 326 provided on the upper surface of the base 324a of the primary structure 324. As a result, the support structure 328 is guided by the guide groove 326 to move in the apparatus width direction.

For example, the support plate 256 is provided with a protrusion 258 protruding from an outer peripheral surface 256a, wherein the vertical direction is defined as a plate thickness direction. Further, a through-hole 258a is provided (formed) in the protrusion 258 so as to penetrate the protrusion 258 in the vertical direction. In addition, the column structure 328b of the support structure 328 is inserted into the through-hole 258a.

### —Regulator 332 of First Mover 320—

As shown in FIG. 7, for example, the regulator 332 may include: a screw shaft 334 extending in the apparatus depth direction; and a pair of support plates 336 configured to be capable of rotatably supporting the screw shaft 334.

A male screw 334a is provided (formed) on an outer peripheral surface of the screw shaft 334, and the male screw 334a of the screw shaft 334 is screwed into the female screw 330 of the primary structure 324. Thereby, a ball screw structure (which in known) including components such as the screw shaft 334, the female screw 330 and balls (not shown) is provided. Further, the driver 340 is provided so as to rotate the screw shaft 334.

In such a configuration, by rotating the screw shaft 334 by the driver 340 in one direction (first direction), the first mover 320 moves the resonance coil 212 and the shield plate 224 toward an inner portion of the process vessel 203 in the apparatus depth direction. Specifically, by rotating the screw shaft 334 by the driver 340 in the first direction, the primary structure 324 and the support structure 328 are moved toward the inner portion of the process vessel 203 in the apparatus depth direction. Further, by moving the primary structure 324 and the support structure 328 toward the inner portion of the process vessel 203 in the apparatus depth direction, the resonance coil 212 and the shield plate 224 are moved toward the inner portion of the process vessel 203 in the apparatus depth direction via the support plate 256.

On the other hand, by rotating the screw shaft 334 by the driver 340 in the other direction (second direction), the first mover 320 moves the resonance coil 212 and the shield plate 224 toward a front end of the process vessel 203 in the apparatus depth direction. Specifically, by rotating the screw shaft 334 by the driver 340 in the second direction, the primary structure 324 and the support structure 328 are moved toward the front end of the process vessel 203 in the apparatus depth direction. Further, by moving the primary structure 324 and the support structure 328 toward the front end of the process vessel 203 in the apparatus depth direction, the resonance coil 212 and the shield plate 224 are moved toward the front end of the process vessel 203 in the apparatus depth direction via the support plate 256. In a manner described above, the resonance coil 212 is moved integrally with the shield plate 224.

For example, even when the resonance coil 212 and the shield plate 224 are moved in the apparatus width direction by the second mover 370, movements of the resonance coil 212 and the shield plate 224 by the second mover 370 can be absorbed by moving the support structure 328 in the apparatus width direction while the support structure 328 is being guided by the guide groove 326.

### —Second Mover 370—

As shown in FIG. 6, for example, the second mover 370 is provided on the base plate 248 to be located close to a rear end (upper end in the page) of the base plate 248 in the apparatus depth direction and also close to the lateral end (left end in the page) of the base plate 248 in the apparatus width direction.

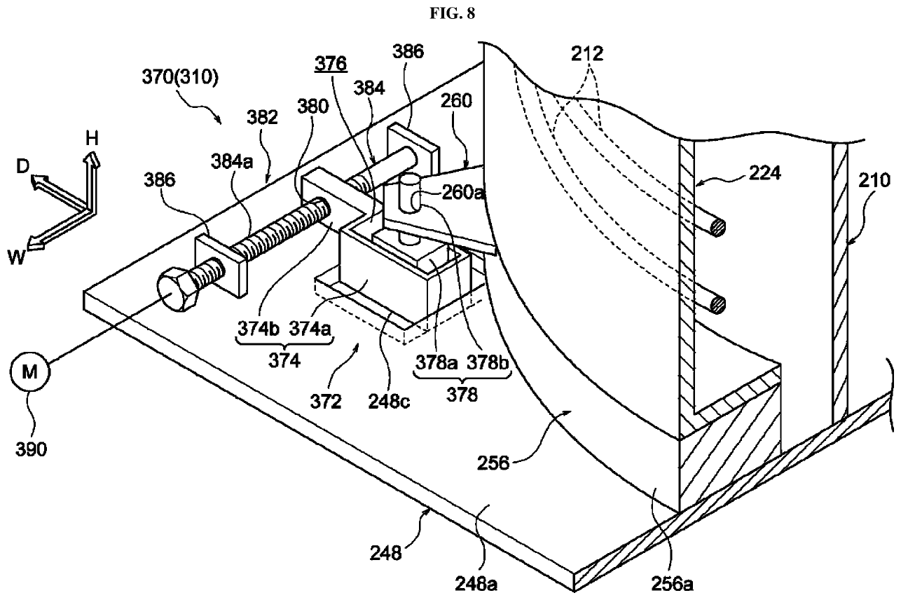

As shown in FIG. 8, the second mover 370 may include: a movable structure 372 indirectly attached to the resonance coil 212 and configured to move integrally with the resonance coil 212; a regulator (which is an adjusting structure) 382 serving as a structure configured to adjust a position of the movable structure 372 by moving the movable structure 372 when operated; and a driver (which is a driving structure) 390 such as a stepping motor.

### —Movable Structure 372 of Second Mover 370—

As shown in FIG. 8, the movable structure 372 may include a primary structure (main structure) 374 and a support structure 378 supported by the primary structure 374.

The primary structure 374 may include: a base 374a of a rectangular parallelepiped shape extending in the apparatus depth direction; and an extension structure 374b of a plate shape extending from the base 374a toward an inner portion of the base plate 248 in the apparatus depth direction. A lower end portion of the base 374a is inserted into a guide groove 248c provided (formed) on the upper surface 248a of the base plate 248.

As a result, the primary structure 374 is guided by the guide groove 248c to move in the apparatus width direction. Further, a guide groove 376 extending in the apparatus depth direction is provided (formed) on an upper surface of the base 374a.

Further, the extension structure 374b is of a rectangular shape extending in the apparatus depth direction when viewed from the apparatus width direction with a plate thickness direction being the apparatus width direction. A female screw 380 is provided (formed) in the extension structure 374b so as to penetrate the extension structure 374b in the apparatus width direction.

For example, the support structure 378 may include: a base 378a of a rectangular parallelepiped shape extending in the apparatus depth direction; and a column structure 378b of a column shape projecting upward from the base 378a. A portion of the base 378a other than an upper end portion thereof is inserted into the guide groove 376 provided on the upper surface of the base 374a of the primary structure 374. As a result, the support structure 378 is guided by the guide groove 376 to move in the apparatus depth direction.

For example, the support plate 256 is provided with a protrusion 260 protruding from the outer peripheral surface 256a, wherein the vertical direction is defined as the plate thickness direction. Further, a through-hole 260a is provided (formed) in the protrusion 260 so as to penetrate the protrusion 260 in the vertical direction. In addition, the column structure 378b of the support structure 378 is inserted into the through-hole 260a.

### —Regulator 382 of Second Mover 370—

As shown in FIG. 8, for example, the regulator 382 may include: a screw shaft 384 extending in the apparatus width direction; and a pair of support plates 386 configured to be capable of rotatably supporting the screw shaft 384.

A male screw 384a is provided (formed) on an outer peripheral surface of the screw shaft 384, and the male screw 384a of the screw shaft 384 is screwed into the female screw 380 of the primary structure 374. Thereby, a ball screw structure (which in known) including components such as the screw shaft 384, the female screw 380 and balls (not shown) is provided. Further, the driver 390 is provided so as to rotate the screw shaft 384.

In such a configuration, by rotating the screw shaft 384 by the driver 390 in one direction (first direction), the second mover 370 moves the resonance coil 212 and the shield plate 224 toward one end (first side) of the process vessel 203 in the apparatus width direction. Specifically, by rotating the screw shaft 384 by the driver 390 in the first direction, the primary structure 374 and the support structure 378 are moved toward the first side of the process vessel 203 in the apparatus width direction. Further, by moving the primary structure 374 and the support structure 378 toward the first side of the process vessel 203 in the apparatus width direction, the resonance coil 212 and the shield plate 224 are moved toward the first side of the process vessel 203 in the apparatus width direction via the support plate 256.

On the other hand, by rotating the screw shaft 384 by the driver 390 in the other direction (second direction), the second mover 370 moves the resonance coil 212 and the shield plate 224 toward the other end (second side) of the process vessel 203 in the apparatus width direction. Specifically, by rotating the screw shaft 384 by the driver 390 in the second direction, the primary structure 374 and the support structure 378 are moved toward the second side of the process vessel 203 in the apparatus width direction. Further, by moving the primary structure 374 and the support structure 378 toward the second side of the process vessel 203 in the apparatus width direction, the resonance coil 212 and the shield plate 224 are moved toward the second side of the process vessel 203 in the apparatus width direction via the support plate 256.

### <Controller 221>

As shown in FIG. 1, a controller 221 is configured to be capable of controlling: the APC valve 242, the valve 243b and the vacuum pump 246 through a signal line “A”; the susceptor elevator 268 through a signal line “B”; and a heater power regulator 276 through a signal line “C”. The controller 221 is further configured to be capable of controlling: the gate valve 244 through a signal line “D”; the RF sensor 272, the high frequency power supply 273 and the matcher 274 through a signal line “E”; and the MFCs 252a, 252b and 252c and the valves 253a, 253b, 253c and 243a through a signal line “F”.

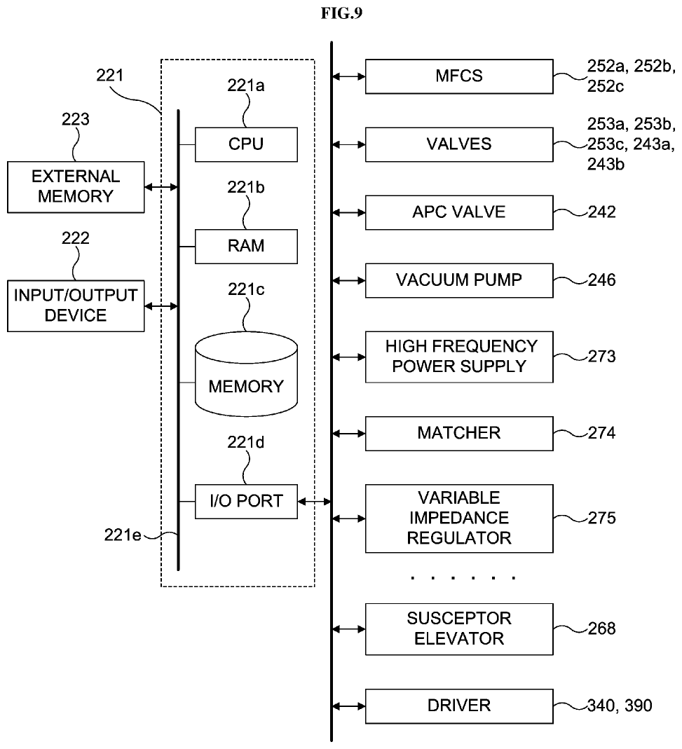

As shown in FIG. 9, for example, the controller 221 is constituted by a computer including a CPU (Central Processing Unit) 221a, a RAM (Random Access Memory) 221b, a memory 221c and an I/O port 221d. The RAM 221b, the memory 221c and the I/O port 221d may exchange data with the CPU 221a through an internal bus 221e. For example, an input/output device 222 constituted by components such as a touch panel and a display may be connected to the controller 221.

According to the present embodiments, the input/output device 222 is configured to receive an operation command and the process conditions serving as movement information for moving the resonance coil 212. Further, the input/output device 222 is configured to displays an amount of movement of the resonance coil 212 with respect to a predetermined reference position.

—Memory 221c—

The memory 221c may be embodied by a component such as a flash memory and a hard disk drive (HDD). For example, a control program configured to control operations of the substrate processing apparatus 100 and a process recipe in which information such as sequences and conditions of a substrate processing described later is stored may be readably stored in the memory 221c.

The process recipe is obtained by combining steps of the substrate processing described later such that the controller 221 can execute the steps by the CPU 221a to acquire a predetermined result, and functions as a program. Hereinafter, the process recipe and the control program may be collectively or individually referred to as a “program”. Thus, in the present specification, the term “program” may refer to the process recipe alone, may refer to the control program alone, or may refer to both of the process recipe and the control program. Further, the RAM 221b functions as a memory area (work area) where a program or data read by the CPU 221a is temporarily stored.

According to the present embodiments, each process condition is stored in the memory 221c. The process conditions may include at least one conditions among a temperature of the wafer 200 to be processed, an inner pressure of the process chamber 201, a type of the process gas used for processing the wafer 200, a flow rate of the process gas used for processing the wafer 200 and the electric power supplied to the resonance coil 212.

—I/O Port 221d—

The I/O port 221d is electrically connected to the components described above such as the MFCs 252a, 252b and 252c, the valves 253a, 253b, 253c, 243a and 243b, the gate valve 244, the APC valve 242, the vacuum pump 246, the RF sensor 272, the high frequency power supply 273, the matcher 274, the susceptor elevator 268, a variable impedance regulator 275, a heater power regulator 276 and the drivers 340 and 390.

—CPU 221a—

The CPU 221a is configured to read and execute the control program stored in the memory 221c, and to read the process recipe stored in the memory 221c in accordance with an instruction such as the operation command inputted via the input/output device 222. The CPU 221a serves as an example of a control structure.

For example, the CPU 221a is configured to be capable of controlling various operations, in accordance with the process recipe, such as an operation of adjusting an opening degree of the APC valve 242, an opening and closing operation of the valve 243b and a start and stop of the vacuum pump 246 via the I/O port 221d and the signal line “A”. Further, the CPU 221a is configured to be capable of controlling various operations, in accordance with the process recipe, such as an elevating and lowering operation of the susceptor elevator 268 via the I/O port 221d and the signal line “B”; a power supply amount adjusting operation (temperature adjusting operation) to the heater 217b by the heater power regulator 276 via the I/O port 221d and the signal line “C”; and an opening and closing operation of the gate valve 244 via the I/O port 221d and the signal line “D”. Further, the CPU 221a is configured to be capable of controlling various operations, in accordance with the process recipe, such as controlling operations for the RF sensor 272, the matcher 274 and the high frequency power supply 273 via the I/O port 221d and the signal line “E”; and flow rate adjusting operations for various gases by the MFCs 252a, 252b and 252c and opening and closing operations of the valves 253a, 253b, 253c, 243a via the I/O port 221d and the signal line “F”.

The controller 221 may be embodied by installing the above-described program stored in an external memory 223 into the computer. For example, the external memory 223 may include a magnetic tape, a magnetic disk such as a flexible disk and a hard disk, an optical disk such as a CD and a DVD, a magneto-optical disk such as an MO and a semiconductor memory such as a USB memory and a memory card. The memory 221c or the external memory 223 may be embodied by a non-transitory computer readable recording medium. Hereafter, the memory 221c and the external memory 223 may be collectively or individually referred to as a “recording medium”. Thus, in the present specification, the term “recording medium” may refer to the memory 221c alone, may refer to the external memory 223 alone, or may refer to both of the memory 221c and the external memory 223. The program may be provided to the computer without using the external memory 223. For example, the program may be supplied to the computer using a communication interface such as the Internet and a dedicated line.

### <Actions>

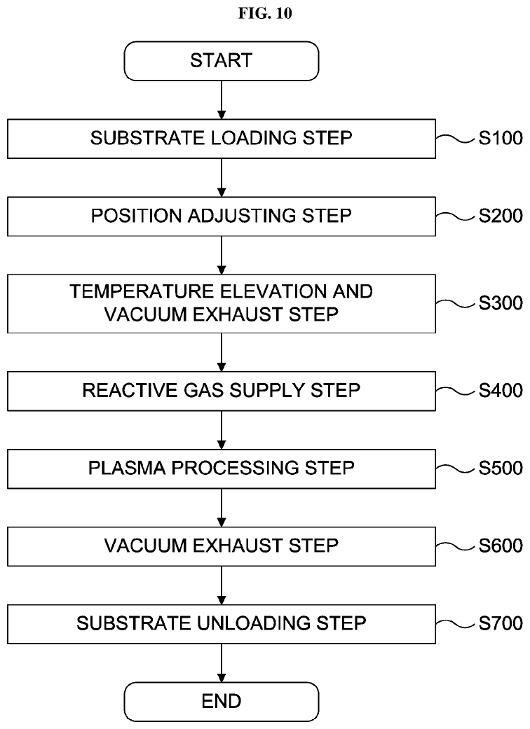

Subsequently, a method of manufacturing a semiconductor device using the substrate processing apparatus 100 according to the embodiments of the present disclosure will be described with reference to a flow chart shown in FIG. 10 while comparing the method mentioned above with a method of manufacturing the semiconductor device using a substrate processing apparatus 500 according to a comparative example of the embodiments of the present disclosure.

### <Configuration of Substrate Processing Apparatus 500>

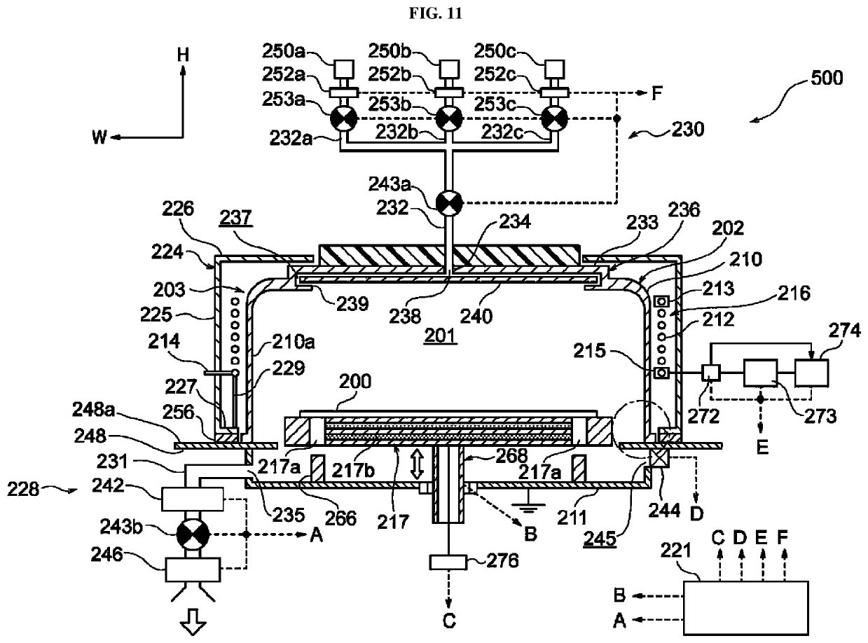

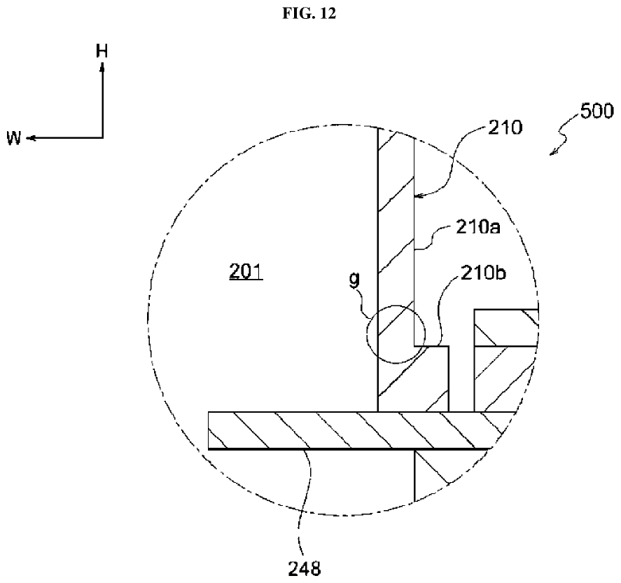

First, a configuration of the substrate processing apparatus 500 according to the comparative example will be described, mainly with respect to portions different from the substrate processing apparatus 100 according to the present embodiments, with reference to FIGS. 11 and 12. No SiN film is formed on the inner peripheral surface of the upper vessel 210 of the substrate processing apparatus 500. Further, in the process chamber 201 of the substrate processing apparatus 500, the cylindrical structure 290 (of the substrate processing apparatus 100) is not provided at the lower end portion of the upper vessel 210 along the inner peripheral surface of the upper vessel 210. Further, in the substrate processing apparatus 500, a distance between the outer peripheral surface of the upper vessel 210 and the peripheral surface of the resonance coil 212 at the lower end portion of the resonance coil 212 is set to be the same as the distance at the other portions of the resonance coil 212. In other words, in the substrate processing apparatus 500, the distance between the outer peripheral surface of the upper vessel 210 and the peripheral surface of the resonance coil 212 is set to be the same along the vertical direction. Accordingly, in the substrate processing apparatus 500, the distance between the peripheral surface of the lower end portion of the resonance coil 212 and the outer peripheral surface of the upper vessel 210 is set to be less than 8 mm.

Furthermore, the substrate processing apparatus 500 does not include the mover 310 (of the substrate processing apparatus 100) configured to move the resonance coil 212 with respect to the process vessel 203.

### <Method of Manufacturing Semiconductor Device>

The method of manufacturing the semiconductor device according to the present embodiments is performed by using the substrate processing apparatus 100, for example, as a part of a manufacturing process of the semiconductor device such as a flash memory. Further, the method of manufacturing the semiconductor device according to the comparative example is performed by using the substrate processing apparatus 500. In the following description, operations of components constituting the substrate processing apparatus 100 or constituting the substrate processing apparatus 500 are controlled by the CPU 221a.

As an example of the process conditions using the plasma according to the present embodiments (and according to the comparative example), the temperature of the wafer 200 to be processed is set to be within a range from 600° C. to 800° C., the inner pressure of the process chamber 201 is set to be within a range from 40 Pa to 60 Pa, and a concentration of the H2 gas is set to be within a range from 25% to 35%.

In the substrate processing apparatus 100, steps S100, S200, S300, S400, S500, S600 and S700 shown in FIG. 10 are performed in this order. On the other hand, in the substrate processing apparatus 500, the steps S100, S300, S400, S500, S600 and S700 shown in FIG. 10 are performed in this order.

On the surface of the wafer 200 to be processed in the substrate processing according to the present embodiments (and according to the comparative example), for example, a trench including a convex-concave structure with a high aspect ratio is formed in advance. For example, at least a surface of the trench is configured as a silicon layer. According to the present embodiments (and according to the comparative example), The oxidation process serving as a process using the plasma is performed with respect to the silicon layer exposed on an inner wall of the trench.

### <Substrate Loading Step S100>

In the substrate loading step S100 shown in FIG. 10, the wafer 200 is transferred (or loaded) into the process chamber 201 and accommodated therein. Specifically, the susceptor 217 is lowered to a position of transferring the wafer 200 by the susceptor elevator 268 shown in FIG. 1 or FIG. 11 such that the wafer lift pins 266 pass through the through-holes 217a of the susceptor 217.

Subsequently, the gate valve 244 is opened, and the wafer 200 is transferred into the process chamber 201 using the wafer transfer structure (not shown) from a vacuum transfer chamber (not shown) provided adjacent to the process chamber 201. The wafer 200 loaded into the process chamber 201 is placed on and supported by the wafer lift pins 266 (which protrude from a surface of the susceptor 217) in a horizontal orientation. After the wafer 200 is loaded into the process chamber 201, the wafer transfer structure is retracted to a position outside the process chamber 201, and the gate valve 244 is closed to hermetically seal (or close) an inside of the process chamber 201. Thereafter, by elevating the susceptor 217 using the susceptor elevator 268, the wafer 200 is placed on and supported by an upper surface of the susceptor 217.

### <Position Adjusting Step S200>

In the position adjusting step S200, based on distance information (that is, the distance measured in advance) between the peripheral surface of the lower end portion of the resonance coil 212 and the outer peripheral surface of the upper vessel 210, the first mover 320 moves the resonance coil 212 in the apparatus depth direction and the second mover 370 moves the resonance coil 212 in the apparatus width direction.

Specifically, the driver 340 and the driver 390 shown in FIGS. 7 and 8 are operated based on the distance information. The driver 340 shown in FIG. 7 rotates the screw shaft 334. By rotating the screw shaft 334 by the driver 340, the primary structure 324 and the support structure 328 are moved in the apparatus depth direction. Further, by moving the primary structure 324 and the support structure 328 in the apparatus depth direction, the resonance coil 212 and the shield plate 224 are moved in the apparatus depth direction via the support plate 256. Further, since the support structure 328 is guided by the guide groove 326 to move in the apparatus width direction, the position of the resonance coil 212 in the apparatus width direction is not restricted by the driver 340 in operation.

Further, the driver 390 shown in FIG. 8 rotates the screw shaft 384. By rotating the screw shaft 384 by the driver 390, the primary structure 374 and the support structure 378 are moved in the apparatus width direction. Further, by moving the primary structure 374 and the support structure 378 in the apparatus width direction, the resonance coil 212 and the shield plate 224 are moved in the apparatus width direction via the support plate 256. Further, since the support structure 378 is guided by the guide groove 376 to move in the apparatus depth direction, the position of the resonance coil 212 in the apparatus depth direction is not restricted by the driver 390 in operation.

By moving the resonance coil 212 relative to the upper vessel 210 of the process vessel 203 in a manner described above, even when the variation in the shape of the process vessel 203 occurs, it is possible to set the distance between the peripheral surface of the lower end portion of the resonance coil 212 and the outer peripheral surface of the upper vessel 210 set to be equal to or greater than 8 mm.

Then, while the wafer 200 is being processed in the process chamber 201, the drivers 340 and 390 are in a non-operating state. In other words, while the wafer 200 is being processed in the process chamber 201, a relative relationship between the resonance coil 212 and the upper vessel 210 of the process vessel 203 is maintained.

For example, when the distance between the peripheral surface of the lower end portion of the resonance coil 212 and the outer peripheral surface of the upper vessel 210 is set to be equal to or greater than 8 mm in the distance information measured in advance, in the position adjusting step S200, the resonance coil 212 is not moved relative to the upper vessel 210 of the process 203.

### <Temperature Elevation and Vacuum Exhaust Step S300>

In the temperature elevation and vacuum exhaust step S300, the temperature of the wafer 200 loaded into the process chamber 201 is elevated. The heater 217b shown in FIG. 1 or FIG. 11 is heated in advance, and the wafer 200 is heated by placing the wafer 200 on the susceptor 217 where the heater 217b is embedded. In the present step, the wafer 200 is heated such that the temperature of the wafer 200 reaches and is maintained at a target temperature. Further, while the wafer 200 is being heated, the vacuum pump 246 vacuum-exhausts an inner atmosphere of the process chamber 201 through the gas exhaust pipe 231 such that the inner pressure of the process chamber 201 reaches and is maintained at a predetermined pressure. The vacuum pump 246 is continuously operated at least until the substrate unloading step S700 described later is completed.

### <Reactive Gas Supply Step S400>

In the reactive gas supply step S400, as a supply of the reactive gas, a supply of the O2 gas serving as the oxygen-containing gas and a supply of the H2 gas serving as the hydrogen-containing gas are started. Specifically, the valves 253a and 253b shown in FIG. 1 or FIG. 11 are opened to supply the O2 gas and the H2 gas into the process chamber 201 while flow rates of the O2 gas and the H2 gas are adjusted by the MFCs 252a and 252b, respectively. In the present step, for example, the flow rate of the O2 gas is adjusted (or set) to a predetermined flow rate within a range from 20 sccm to 2,000 sccm. In addition, for example, the flow rate of the H2 gas is adjusted (or set) to a predetermined flow rate within a range from 20 sccm to 1,000 sccm.

In the present step, for example, the inner atmosphere of the process chamber 201 is exhausted by adjusting the opening degree of the APC valve 242 such that the inner pressure of the process chamber 201 reaches and is maintained at a target pressure. The O2 gas and the H2 gas are continuously supplied into the process chamber 201 until the plasma processing step S500 described later is completed.

### <Plasma Processing Step S500>

After the inner pressure of the process chamber 201 is stabilized, in the plasma processing step S500, a supply of the high frequency power to the resonance coil 212 shown in FIG. 1 or FIG. 11 is started from the high frequency power supply 273 via the RF sensor 272. According to the present embodiments, for example, the high frequency power of 27.12 MHz is supplied from the high frequency power supply 273 to the resonance coil 212. For example, the high frequency power supplied to the resonance coil 212 is a predetermined power within a range from 100 W to 5,000 W.

Thereby, the high frequency electric field is generated in the plasma generation space 201a (see FIG. 3) to which the O2 gas and the H2 gas are supplied. As a result, the donut-shaped induction plasma whose plasma density is the highest at a height corresponding to the electric midpoint of the resonance coil 212 in the plasma generation space 201a is excited by the high frequency electric field. Each of the O2 gas and the H2 gas is excited into a plasma state and dissociates. As a result, reactive species such as oxygen radicals (oxygen active species) containing oxygen, oxygen ions, hydrogen radicals (hydrogen active species) containing hydrogen and hydrogen ions may be generated.

Then, the radicals and the ions generated by the induction plasma are supplied to the trench on the surface of the wafer 200 placed on the susceptor 217 in the substrate processing space 201b (see FIG. 3). The radicals and ions supplied to the trench react with a side wall of the trench. Thereby, the silicon layer on the surface of the trench is modified into a silicon oxide layer.

After a predetermined process time (for example, 10 seconds to 300 seconds) has elapsed, the supply of the high frequency power from the high frequency power supply 273 is stopped to stop a plasma discharge in the process chamber 201. In addition, the valves 253a and 253b are closed to stop the supply of the O2 gas and the supply of the H2 gas into the process chamber 201. Thereby, the plasma processing step S500 is completed.

In the present step, in the substrate processing apparatuses 100 and 500, the H2 gas is supplied through an upper portion of the process chamber 201, flows downward along the inner peripheral surface of the upper vessel 210, and hits the upper surface 248a of the base plate 248 to change a flow direction thereof. The H2 gas may stagnate at a portion where the flow direction is changed.

In the substrate processing apparatus 500 shown in FIG. 11, the distance between the peripheral surface of the lower end portion of the resonance coil 212 and the outer peripheral surface of upper vessel 210 is set to be less than 8 mm. Therefore, a plasma strength of the induction plasma at the portion where the H2 gas stagnates is increased. As a result, the H2 gas at the portion (where the H2 gas stagnates) reacts with the induction plasma to form the SiOH film on the inner peripheral surface of the lower end portion of the upper vessel 210. Further, the SiOH film contains a three-membered ring and a four-membered ring. Thereby, the SiOH film is unstable and brittle with respect to the SiO₂ of a random structure.

On the other hand, in the substrate processing apparatus 100 shown in FIG. 1, the distance between the peripheral surface of the lower end portion of the resonance coil 212 and the outer peripheral surface of the upper vessel 210 is set to be equal to or greater than 8 mm. That is, the above-mentioned distance is set to be greater at the lower end portion of the resonance coil 212 than at the other portions of the resonance coil 212. In other words, the distance between the peripheral surface of the lower end portion of the resonance coil 212 (which is close to the portion where the SiOH film is formed on the inner peripheral surface of the upper vessel 210) and the outer peripheral surface of the upper vessel 210 is set to be equal to or greater than 8 mm, and is also greater than the distance between peripheral surfaces of the other portions of the resonance coil 212 and the outer peripheral surface of the upper vessel 210. Further in other words, the distance between the peripheral surface of the resonance coil 212 (which is close to the portion of the inner peripheral surface of the upper vessel 210 where the SiOH film is formed) and the outer peripheral surface of the upper vessel 210 is set to be greater than the distance between the peripheral surface of the resonance coil 212 (which is close to a portion of the inner peripheral surface of the upper vessel 210 where the SiOH film is not formed) and the outer peripheral surface of the upper vessel 210.

As a result, in the substrate processing apparatus 100, the plasma strength of the induction plasma at the portion where the H2 gas stagnates is weakened (decreased). Therefore, a thickness of the SiOH film formed on an inner peripheral surface of a lower end portion of the cylindrical structure 290 is reduced.

Further, in the substrate processing apparatus 100, the cylindrical structure 290 of a cylindrical shape is provided at the lower end portion of the upper vessel 210 along the inner peripheral surface of the upper vessel 210. By forming the SiOH film on the inner peripheral surface of the cylindrical structure 290, the thickness of the SiOH film formed on the inner peripheral surface of the lower end portion of the upper vessel 210 of the substrate processing apparatus 100 is reduced.

Thus, the thickness of the SiOH film formed on the inner peripheral surface of the lower end portion of the upper vessel 210 of the substrate processing apparatus 100 is smaller than the thickness of the SiOH film formed on the inner peripheral surface of the lower end portion of the upper vessel 210 of the substrate processing apparatus 500. In other words, the thickness of the SiOH film formed on the inner peripheral surface of the lower end portion of the upper vessel 210 of the substrate processing apparatus 500 is greater than the thickness of the SiOH film formed on the inner peripheral surface of the lower end portion of the upper vessel 210 of the substrate processing apparatus 100.

In the substrate processing apparatus 100, the thickness of the SiOH film formed on the inner peripheral surface of the cylindrical structure 290 includes a thickness of zero. That is, in the substrate processing apparatus 100, the SiOH film may not be formed on the inner peripheral surface of the cylindrical structure 290 in some cases.

### <Vacuum Exhaust Step S600>

After the supply of the O2 gas and the supply of the H2 gas are stopped, in the vacuum exhaust step S600, the inner atmosphere of the process chamber 201 is vacuum-exhausted through the gas exhaust pipe 231 shown in FIG. 1 or FIG. 11. Thereby, a gas such as the O2 gas, the H2 gas and an exhaust gas generated from a reaction therebetween in the process chamber 201 can be exhausted out of the process chamber 201. Thereafter, the opening degree of the APC valve 242 is adjusted such that the inner pressure of the process chamber 201 is adjusted to substantially the same pressure as that of the vacuum transfer chamber (to which the wafer 200 is to be transferred: not shown) provided adjacent to the process chamber 201.

### <Substrate Unloading Step S700>

After the inner pressure of the process chamber 201 is adjusted to a predetermined pressure, in the substrate unloading step S700, the susceptor 217 shown in FIG. 1 or FIG. 11 is lowered to the position of transferring the wafer 200 until the wafer 200 is supported by the wafer lift pins 266. Then, the gate valve 244 is opened, and the wafer 200 is transferred (unloaded) out of the process chamber 201 by using the wafer transfer structure (not shown). Thereby, the substrate processing according to the present embodiments (and according to the comparative example) is completed.

### <Maintenance Step>

After the substrate processing is performed a plurality of times, a maintenance step is performed on the substrate processing apparatuses 100 and 500. The maintenance step will be described.

—Stopping Supply of Electric Power to Heater 217b—

In the substrate processing apparatuses 100 and 500 after the substrate processing is performed, a supply of the electric power to the heater 217b is stopped. As a result, a temperature of the lower end portion of the upper vessel 210 close to the heater 217b drops the most. In other words, a temperature change (temperature variation) at the lower end portion of the upper vessel 210 close to the lower end portion of the resonance coil 212 increases. As the temperature change at the lower end portion of the upper vessel 210 increases, regarding the SiOH film formed on the inner peripheral surface of the lower end portion of the upper vessel 210, a temperature difference may occur between a portion of the SiOH film facing the upper vessel 210 and a portion of the SiOH film facing the process chamber 201.

As described above, the thickness of the SiOH film formed on the inner peripheral surface of the lower end portion of the upper vessel 210 of the substrate processing apparatus 500 is greater than the thickness of the SiOH film formed on the inner peripheral surface of the lower end portion of the upper vessel 210 of the substrate processing apparatus 100. Therefore, in the substrate processing apparatus 500, the temperature difference between the portion of the SiOH film facing the upper vessel 210 and the portion of the SiOH film facing the process chamber 201 may increase. As a result, in the substrate processing apparatus 500, the crack may occur in the SiOH film due to the temperature difference.

On the other hand, the thickness of the SiOH film formed on the inner peripheral surface of the lower end portion of the upper vessel 210 of the substrate processing apparatus 100 is smaller than the thickness of the SiOH film formed on the inner peripheral surface of the lower end portion of the upper vessel 210 of the substrate processing apparatus 500. Therefore, it is possible to reduce the temperature difference between the portion of the SiOH film facing the upper vessel 210 and the portion of the SiOH film facing the process chamber 201. As a result, in the substrate processing apparatus 100, it is possible to suppress an occurrence of the crack in the SiOH film due to the temperature difference.

### —Returning to Atmospheric Pressure—

After the supply of the electric power to the heater 217b is stopped, the inner pressure of the process chamber 201 is returned to an atmospheric pressure. Then, the maintenance step is performed on each component of the substrate processing apparatuses 100 and 500 after the inner pressure of the process chamber 201 is returned to the atmospheric pressure.

When the inner pressure of the process chamber 201 is returned to the atmospheric pressure, the side wall of the upper vessel 210 tends to move in the plate thickness direction. As a result, as shown in FIGS. 2 and 12, a slight deformation may occur in a portion (indicated by “g” in the FIGS. 2 and 12) above the flange 210b in the upper vessel 210.

In the substrate processing apparatus 500, due to the deformation, a fine crack generated in the SiOH film develops and reaches the upper vessel 210. Then, the crack may occur in the upper vessel 210.

On the other hand, in the substrate processing apparatus 100, as described above, it is possible to suppress the occurrence of the crack in the SiOH film. Thus, it is also possible to suppress the occurrence of the crack due to the deformation in the portion above the flange 210b in the upper vessel 210.

Further, in the substrate processing apparatus 100, the SiN film is formed on the inner peripheral surface of the upper vessel 210 to protect the upper vessel 210. Therefore, even when the fine crack occurs in the SiOH film, it is also possible to suppress the occurrence of the crack of the upper vessel 210 caused by a development of the fine crack in the SiOH film.

### SUMMARY

According to the present embodiments, it is possible to obtain one or more of the following effects.

Specifically, as described above, in the substrate processing apparatus 100, the distance between the peripheral surface of the resonance coil 212 (which is close to the lower portion of the upper vessel 210) and the outer peripheral surface of the upper vessel 210 is set to be greater than the distance between the peripheral surface of the resonance coil 212 (which is not close to the lower portion of the upper vessel 210) and the outer peripheral surface of the upper vessel 210. In other words, in the substrate processing apparatus 100, the distance between the peripheral surface of the resonance coil 212 (which is close to the portion of the inner peripheral surface of the upper vessel 210 where the SiOH film is formed) and the outer peripheral surface of the upper vessel 210 is set to be greater than the distance between the peripheral surface of the resonance coil 212 (which is close to a portion of the inner peripheral surface of the upper vessel 210 where the SiOH film is not formed) and the outer peripheral surface of the upper vessel 210.

Thus, the thickness of the SiOH film formed on the inner peripheral surface of the lower end portion of the upper vessel 210 of the substrate processing apparatus 100 is smaller than the thickness of the SiOH film formed on the inner peripheral surface of the lower end portion of the upper vessel 210 of the substrate processing apparatus 500. Therefore, as compared with the substrate processing apparatus 500 according to the comparative example, in the substrate processing apparatus 100, it is possible to suppress the occurrence of the crack of the upper vessel 210 due to the SiOH film formed on the inner peripheral surface of the upper vessel 210.

Further, in the substrate processing apparatus 100, the distance between the peripheral surface of each of the other portions (that is, portions other than the lower portion) of the resonance coil 212 and the outer peripheral surface of the upper vessel 210 is set to be smaller than the distance between the peripheral surface of the lower end portion of the resonance coil 212 and the outer peripheral surface of the upper vessel 210. Therefore, it is possible to set (adjust) a plasma distribution in the process chamber 201 to a desired distribution.

Further, in the substrate processing apparatus 100, the SiN film serving as the protection film for protecting the upper vessel 210 is formed on the inner peripheral surface of the upper vessel 210. Therefore, as compared to a case where the protection film is not formed, even when the crack occurs in the SiOH film, it is possible to suppress the occurrence of the crack of the upper vessel 210 caused by the development of the fine crack in the SiOH film. In other words, as compared to the case where the protection film is not formed, it is possible to suppress the occurrence of the crack of the upper vessel 210 even when the fine crack occurs in the SiOH film.

Further, in the substrate processing apparatus 100, the cylindrical structure 290 is provided along the portion of inner peripheral surface of the upper vessel 210 where the SiOH film is formed. In other words, the cylindrical structure 290 made of SiO₂ is provided along the lower end portion of the inner peripheral surface of the upper vessel 210. As a result, by forming the SiOH film on the inner peripheral surface of the cylindrical structure 290, it is possible to reduce the thickness of the SiOH film formed on the inner peripheral surface of the lower end portion of the upper vessel 210.

Further, in the substrate processing apparatus 100, the temperature change (temperature variation) at the lower end portion of the upper vessel 210 close to the lower end portion of the resonance coil 212 increases. In addition, the distance between the peripheral surface of the lower end portion of the resonance coil 212 and the outer peripheral surface of the upper vessel 210 is set to be equal to or greater than 8 mm. That is, the distance between the peripheral surface of the resonance coil 212 (which is close to the portion of the upper vessel 210 where the temperature change is large) and the outer peripheral surface of the upper vessel 210 is set to be equal to or greater than 8 mm.

For example, when the thickness of the SiOH film (which is formed on the portion where the temperature change is large) increases, the crack may easily occur in the SiOH film as described above. However, the distance between the peripheral surface of the resonance coil 212 (which is close to the portion of the upper vessel 210 where the temperature change is large) and the outer peripheral surface of the upper vessel 210 is set to be equal to or greater than 8 mm. Therefore, by suppressing a formation of the SiOH film in the portion where the temperature change is large in the upper vessel 210, it is possible to suppress the occurrence of the crack in the SiOH film.

Further, in the method of manufacturing the semiconductor device and in a program according to the present embodiments, the position adjusting step of adjusting the distance between the outer peripheral surface of the upper vessel 210 and the peripheral surface of the resonance coil 212. As a result, for example, even when the distance between the peripheral surface of the lower end portion of the resonance coil 212 and the outer peripheral surface of the upper vessel 210 is less than 8 mm, by adjusting relative positions of the resonance coil 212 and the upper vessel 210, it is possible to set the distance to be equal to or greater than 8 mm.

### <Other Embodiments of Present Disclosure>

While the technique of the present disclosure is described in detail by way of the embodiments described above, the technique of the present disclosure is not limited thereto. It is apparent to those skilled in the art that the technique of the present disclosure may be modified in various ways without departing from the scope thereof. For example, the embodiments described above are described by way of an example in which the resonance coil 212 is moved relative to the process vessel 203 by moving the resonance coil 212 with respect to the process vessel 203. However, the resonance coil 212 may be moved relative to the process vessel 203 by moving the process vessel 203 with respect to the resonance coil 212.

For example, the embodiments described above are described by way of an example in which the SiN film is formed on the inner peripheral surface of the upper vessel 210 to protect the upper vessel 210. However, a step of forming the SiN film on the inner peripheral surface of the upper vessel 210 may be further provided in the manufacturing process of the semiconductor device.

For example, the embodiments described above are described by way of an example in which the SiN film is formed on the inner peripheral surface of the upper vessel 210 to protect the upper vessel 210. However, instead of or in addition to the SiN film, a protection film capable of protecting the upper vessel 210 (for example, a protection film containing SiN) may be provided.

For example, the embodiments described above are described by way of an example in which the cylindrical structure 290 is made of SiO₂. However, it is sufficient that the SiOH film is formed on the inner peripheral surface in the manufacturing process of the semiconductor device. Further, the cylindrical structure 290 may be made of a material different from SiO₂.

In addition, although not specifically described in the embodiments described above, a method of setting (adjusting) the plasma distribution in the process chamber 201 to a desired distribution by varying (changing) the distance between the outer peripheral surface of the upper vessel 210 and the resonance coil 212 in a circumferential direction of the upper vessel 210 may be used. When using such a method, it is considered that the distance between the peripheral surface of the lower end portion of the resonance coil 212 (which is close to the portion of the inner peripheral surface of the upper vessel 210) and the outer peripheral surface of the upper vessel 210 is set to less than 8 mm. However, by applying the technique of the present disclosure, it is possible to reliably set the distance to be equal to or greater than 8 mm.

In addition, although not specifically described in the embodiments described above, the number of each component described in the present specification is not limited to one, and the number of each component described in the present specification may be two or more unless otherwise specified in the present specification.

For example, the embodiments described above are described by way of an example in which a single wafer type substrate processing apparatus capable of processing one or several substrates at a time is used to form the film. However, the technique of the present disclosure is not limited thereto. For example, the technique of the present disclosure may be preferably applied when a batch type substrate processing apparatus capable of simultaneously processing a plurality of substrates is used to form the film. For example, the embodiments described above are described by way of an example in which a substrate processing apparatus including a hot wall type process furnace is used to form the film. However, the technique of the present disclosure is not limited thereto. For example, the technique of the present disclosure may be preferably applied when a substrate processing apparatus including a cold wall type process furnace is used to form the film.

The process sequences and the process conditions of each process using the substrate processing apparatuses exemplified above may be substantially the same as those of the embodiments or modified examples described above. Even in such a case, it is possible to obtain substantially the same effects according to the embodiments or the modified examples described above.

According to some embodiments of the present disclosure, it is possible to save replacement of the quartz vessel due to occurrence of a crack in the quartz vessel, which is caused by the silicon hydroxide film formed on then inner peripheral surface of the quartz vessel.

What is claimed is:

1. A substrate processing apparatus comprising:
a quartz vessel provided with a process chamber in which a substrate is arranged;
a gas supplier configured to supply a process gas to the process chamber; and
a coil surrounding the quartz vessel and configured to excite the process gas by a plasma generated by supplying a high frequency power to the coil, wherein a distance between the coil and an outer peripheral surface of a first portion of the quartz vessel is set to be greater than a distance between the coil and an outer peripheral surface of a second portion of the quartz vessel, and wherein a silicon hydroxide film is formed on an inner peripheral surface of the first portion and the silicon hydroxide film is not formed on an inner peripheral surface of the second portion.

2. The substrate processing apparatus of claim 1, further comprising
a protection film formed on the inner peripheral surface of the quartz vessel to protect the quartz vessel.

3. The substrate processing apparatus of claim 2, wherein the protection film comprises a silicon nitride film.

4. The substrate processing apparatus of claim 1, further comprising
a partial structure of a cylindrical shape provided in the process chamber and provided along a portion of the inner peripheral surface of the quartz vessel.

5. The substrate processing apparatus of claim 4, wherein the partial structure is provided along the inner peripheral surface of the first portion.

6. The substrate processing apparatus of claim 4, wherein the partial structure is made of quartz.

7. The substrate processing apparatus of claim 1, wherein a distance between a peripheral surface of the coil close to the first portion and the outer peripheral surface of the quartz vessel is set to be equal to or greater than a predetermined value set in advance.

8. The substrate processing apparatus of claim 7, wherein a distance between the peripheral surface of the coil close to a portion of the quartz vessel whereat a temperature change is large and the outer peripheral surface of the quartz vessel is set to be equal to or greater than the predetermined value set in advance.

9. The substrate processing apparatus of claim 7, wherein a distance between the peripheral surface of the coil close to a lower end portion of the quartz vessel and the outer peripheral surface of the quartz vessel is set to be equal to or greater than the predetermined value set in advance.

10. A method of manufacturing a semiconductor device, comprising:
(a) loading a substrate into a process chamber provided in a quartz vessel surrounded by a coil;
(b) setting a distance between a first region of a peripheral surface of the coil close to a first portion of the quartz vessel, wherein a silicon hydroxide film is formed on an inner peripheral surface of the first portion, and an outer peripheral surface of the first portion to be equal to or greater than a predetermined value set in advance and to be greater than a distance between a second region of the peripheral surface of the coil close to a second portion of the quartz vessel, wherein the silicon hydroxide film is not formed on the inner peripheral surface of the second portion, and the outer peripheral surface of the second portion;
(c) supplying a process gas to the process chamber;
(d) exciting the process gas supplied to the process chamber by a plasma by supplying a high frequency power to the coil; and
(e) processing the substrate with the process gas excited by the plasma.

11. The method of claim 10, wherein a partial structure is provided along the inner peripheral surface of the first portion.

12. The method of claim 10, wherein a protection film is formed on the inner peripheral surface of the quartz vessel to protect the quartz vessel.

13. A non-transitory computer-readable recording medium storing a program that causes a substrate processing apparatus, by a computer, to perform:
(a) loading a substrate into a process chamber provided in a quartz vessel surrounded by a coil of a spiral shape;
(b) setting a distance between a first region of a peripheral surface of the coil close to a first portion of the quartz vessel, wherein a silicon hydroxide film is formed on an inner peripheral surface of the first portion, and an outer peripheral surface of the first portion to be equal to or greater than a predetermined value set in advance and to be greater than a distance between a second region of the peripheral surface of the coil close to a second portion of the quartz vessel, wherein the silicon hydroxide film is not formed on the inner peripheral surface of the second portion, and the outer peripheral surface of the second portion;
(c) supplying a process gas to the process chamber;
(d) exciting the process gas supplied to the process chamber by a plasma by supplying a high frequency power to the coil; and
(e) processing the substrate with the process gas excited by the plasma.

14. The non-transitory computer-readable recording medium of claim 13, wherein a partial structure is provided along the inner peripheral surface of the first portion.

15. The non-transitory computer-readable recording medium of claim 13, wherein a protection film is formed on the inner peripheral surface of the quartz vessel to protect the quartz vessel.
